(19) United States
(12) Patent Application Publication
(10) Pub. No.: US 2023/0137769 A1
(43) Pub. Date: May 4, 2023

(54) SOFTWARE THREAD-BASED DYNAMIC MEMORY BANDWIDTH ALLOCATION

(71) Applicant: Intel Corporation, Santa Clara, CA (US)

(72) Inventors: Vijay Anand Mathiyalagan, Chennai (IN); Stephen H. Gunther, Beaverton, OR (US); Shidlingeshwar Khatakalle, Gadhinglaj (IN); Diyanesh Babu Chinnakkonda Vidyapoornachary, Bangalore (IN)

(21) Appl. No.: 17/518,186

(22) Filed: Nov. 3, 2021

(51) Int. Cl. G06F 9/50

(52) U.S. Cl. CPC G06F 9/5016

(57) ABSTRACT

Systems, apparatuses and methods may provide for operating system (OS) technology that determines an average bandwidth consumption with respect to a memory device, wherein the average bandwidth consumption is dedicated to a previous execution of a thread in a multi-threaded execution environment, stores the average bandwidth consumption, and sends the average bandwidth consumption to a power management unit in response to a subsequent execution of the thread being scheduled. Additionally, logic hardware technology may include a first set of registers to accumulate an average bandwidth consumption for a plurality of threads on a per thread basis with respect to the memory device, wherein the average bandwidth consumption corresponds to previous executions of the plurality of threads. The logic hardware technology determines a minimum bandwidth demand based on the average bandwidth consumption and sets a dynamic voltage and frequency scaling point based on the minimum bandwidth demand.

### TECHNICAL FIELD

Embodiments generally relate to memory bandwidth allocation. More particularly, embodiments relate to software thread-based dynamic memory bandwidth allocation.

### BACKGROUND

Dynamic voltage and frequency scaling (DVFS) may allow a computing system to adjust the operating frequency of double data rate (DDR) memory within the system in an effort to match performance to the bandwidth demands on the DDR memory. The reactive nature of conventional DVFS solutions, however, may result in frequency increases that are too long and/or unnecessary altogether.

### BRIEF DESCRIPTION OF THE DRAWINGS

FIG. 1 is a comparative plot of an example of operating frequency versus time for a conventional DVFS solution and DVFS technology according to an embodiment;

FIG. 2 is a block diagram of an example of a computing architecture according to an embodiment;

FIG. 3 is a block diagram of an example of multiple sets of registers according to an embodiment;

FIG. 4 is a flowchart of an example of a method of choosing a DVFS point according to an embodiment;

FIG. 5 is a flowchart of an example of a method of choosing a DVFS point in a memory bandwidth monitoring (MBM) architecture according to an embodiment;

FIGS. 6 and 7 are flowcharts examples methods of operating an operating system scheduler according to an embodiment;

FIG. 8 is a flowchart of an example of a method of operating logic hardware according to an embodiment;

FIG. 9 is a block diagram of an example of a performance-enhanced computing system according to an embodiment;

FIG. 10 is an illustration of an example of a semiconductor package apparatus according to an embodiment;

### DETAILED DESCRIPTION OF EMBODIMENTS

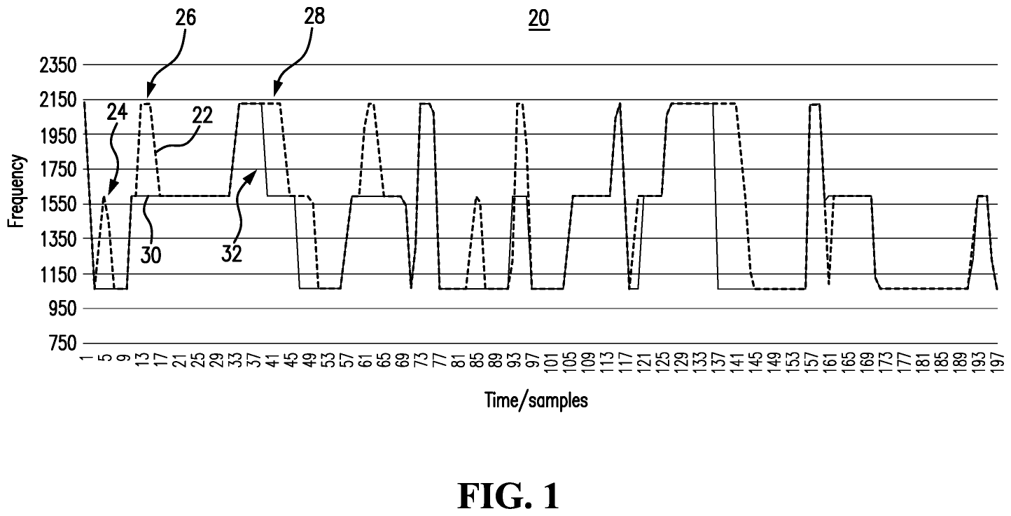

Turning now to FIG. 1, a plot 20 is shown in which a first curve 22 may represent the operating frequency of a memory device (e.g., DDR dynamic random access memory/DRAM or other shared resource) in accordance with a conventional dynamic voltage and frequency scaling (DVFS) solution. The illustrated first curve 22 contains a first frequency spike (e.g., momentary/transient increase) 24, a second frequency spike 26, a third frequency spike 28, and so forth. In general, DVFS may block input/output (10) traffic to and from the memory device when implementing transitions to and from the higher frequencies associated with the frequency spikes 24, 26, 28. Blocking the I0 traffic may have a negative impact on performance.

A second curve 30 represents the operating frequency of a memory device in accordance with enhanced DVFS technology as described herein. In general, the enhanced DVFS technology described herein determines that the first frequency spike 24 and the second frequency spike 26 are unnecessary. Accordingly, the second curve 30 bypasses the first frequency spike 24 and the second frequency spike 26 altogether. Bypassing the first frequency spike 24 and the second frequency spike 26 enhances performance by increasing IO traffic to and from the memory device.

The enhanced DVFS technology described herein may also determine that the duration of the third frequency spike 28 is too long (e.g., due to hysteresis algorithms in the conventional DVFS solution). In such a case, the second curve 30 may include a frequency spike 32 that has a shorter duration. The illustrated second curve 30 therefore further enhances performance by reducing power consumption associated with unnecessary residency at the higher frequency associated with the frequency spike 32.

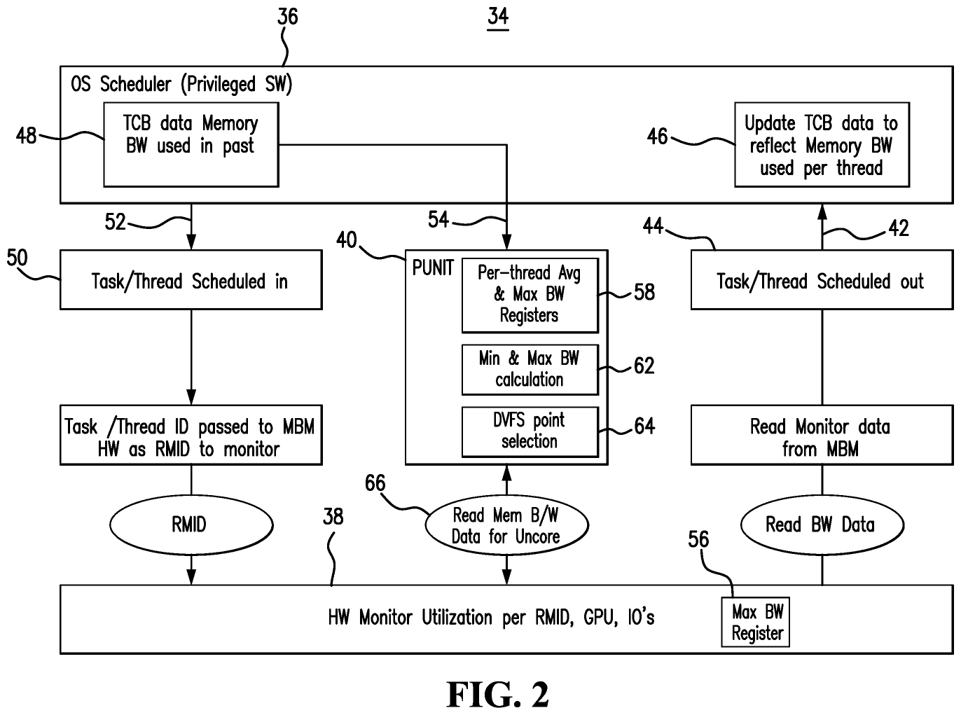

FIG. 2 shows a computing architecture 34 in which an operating system (OS) scheduler 36 (e.g., privileged software/SW) communicates with a power management unit (PUNIT) 40 (e.g., implemented in configurable and/or fixed-functionality hardware) and logic hardware (HW, e.g., implemented in configurable and/or fixed-functionality hardware) 38 that monitors memory bandwidth (BW) utilization per resource monitoring identifier (RMID), graphics processing unit (GPU, e.g., graphics processor) and/or IO device (e.g., via memory bandwidth monitoring/MBM). For example, when application tasks and/or threads are scheduled out at processing block 44 (e.g., previous executions of the threads end), a read interface 42 (e.g., model specific register/MSR) transfers monitor and/or bandwidth data from the logic HW 38 to the OS scheduler 36. A processing block 46 in the OS scheduler 36 updates a data structure such as, for example, a thread control block (TCB) 48 to reflect the memory bandwidth used per thread.

More particularly, the processing block 46 may calculate the average BW consumption per thread and store the result in the TCB 48 (e.g., a pre-existing table that is extended to include BW information). In one example the average BW consumption is the total BW consumed divided by the time duration of the thread. As already noted, the logic hardware 38 monitors (per RMID) the total BW consumed. Additionally, the OS scheduler 36 may have access to information on the duration of the thread. The processing block 46 may also calculate maximum (e.g., peak) BW consumption. In this regard, the illustrated logic hardware 38 includes a register 56 with watermarking capability to obtain the maximum (e.g., peak) bandwidth consumption during the thread runtime. This information is passed to the TCB 48 along with other information. In an embodiment, the time duration of the peak measurement depends on the characteristics of the memory controller.

When tasks and/or threads are scheduled in at processing block 50 (e.g., subsequent executions of the threads begin), a write interface 52 (e.g., MSR) transfers the task/thread identifiers (IDs) to MBM technology in the logic hardware 38 as RMIDs. Additionally, the OS scheduler 36 passes memory bandwidth information of the scheduled threads to the PUNIT 40 via a relatively fast interface 54.

More particularly, the interface 54 that transfers BW information from the TCB 48 to the PUNIT 40 does not create overhead (e.g., additional latency) for the OS scheduler 36. To speed up the information transfer, the interface 54 may include server system on chip (SoC) technology such as FAST MSRs and/or TPMIs (topology aware register and power management capsule interfaces), which are typically faster and create less overhead compared to a traditional MSR.

FAST MSRs may be used for relatively fast writes to uncore (e.g., non-thread execution region) MSRs. There are a few logical processor scope MSRs whose values are observed outside the logical processor. A write to MSR (“WRMSR”) instruction may take over 1000 cycles to complete (e.g., retire) for those MSRs. Accordingly, OSs may avoid writing to the MSRs too often, whereas in many cases it may be advantageous for the OS to write to the MSRs quite frequently for optimal power/performance operation of the logical processor. The model specific “Fast Write MSR” feature reduces this overhead by an order of magnitude to a level of 100 cycles for a selected subset of MSRs.

For example, writes to Fast Write MSRs are posted (e.g., when the WRMSR instruction completes), while the data is still “in transit” within the logical processor. In such a case, software checks the status by querying the logical processor to ensure that data is already visible outside the logical processor. Once the data is visible outside the logical processor, software is ensured that later writes by the same logical processor to the same MSR will be visible later (e.g., will not bypass the earlier writes).

In one example, TPMI creates a flexible, extendable and software-PCIe (Peripheral Component Interconnect Express)-driver-enumerable MMIO (memory mapped IO) interface for power management (PM) features. Traditional register interfaces for PM features may have required changes to ucode, pcode and hardware, while being not enumeration friendly for software. Another advantage of TPMI is the ability to create a contract between software and pcode for feature specific interfaces. A fixed amount of allocated storage in the SoC may be mapped as enumerable MMIO space to software. When extending or adding new features, no fundamental hardware changes are required. In one example, this extension is achieved by specifying the meaning of bits exposed through MMIO, in a consistent manner between software and firmware.

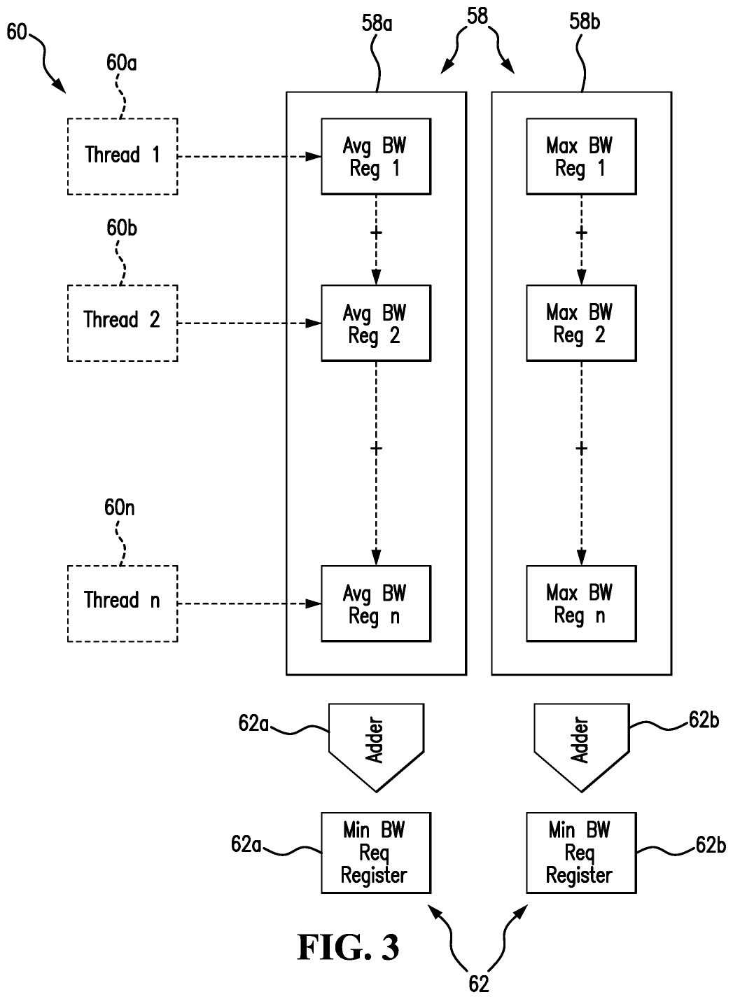

With continuing reference to FIGS. 2 and 3, the PUNIT 40 may include registers 58 (58a, 58b) to accumulate bandwidth consumption information from the interface 54. More particularly, a first set of registers 58a accumulate the average bandwidth consumption for a plurality of threads 60 (60a-60n) on a per thread basis with respect to a memory device and a second set of registers 58b accumulate the maximum bandwidth consumption for the plurality of threads 60 on the per thread basis with respect to the memory device. Thus, “Avg BW Reg 1” and “Max BW Reg 1” are dedicated to a first thread 60a (e.g., in a first logical processor), “Avg BW Reg 2” and “Max BW Reg 2” are dedicated to a second thread 60b (e.g., in a second logical processor), and so forth. The average bandwidth consumption and the maximum bandwidth consumption correspond to previous executions of the plurality of threads 60.

In general, a demand processing block 62 (62a, 62b) determines a minimum bandwidth demand based at least in part on the average bandwidth consumption and determines a maximum bandwidth demand based at least in part on the maximum bandwidth consumption. In the illustrated example, a first component 62a of the demand processing block 62 includes an average bandwidth adder and a minimum bandwidth register. Similarly, a second component 62b of the demand processing block 62 includes a maximum bandwidth adder and a maximum bandwidth register. A DVFS point selection block 64 sets a DVFS point for the memory device based on the minimum bandwidth demand, the maximum bandwidth demand, and a non-thread bandwidth consumption 66 (e.g., uncore data) obtained from the logic hardware 38.

For example, one option (e.g., Option #1) is to distribute the BW demand/requirement equally for all threads (e.g., no bias for higher priority threads). In such a case, the below formulas may be used.

Min memory device BW demand=average BW consumption of all threads+memory device utilization by Uncore

Max (Peak) memory device BW demand=maximum BW consumption of all threads+memory device utilization by Uncore

An implementation optimization conducts the above computations only for threads of interest (e.g., threads having a duration greater than 100 microseconds (μs)). In this regard, kernel threads are usually of a short duration (e.g., less than 100 μs) and may be excluded from the BW allocation calculation. In one example, there is some guardband given in the BW allocation for such short duration threads. This approach can potentially reduce the occurrence of frequent memory device frequency change decisions depending on the implementation. Additionally, the duration can be chosen based on the sensitivity of the BW change, depending on the implementation.

When a thread is scheduled, the average BW and maximum BW demand for the thread is accumulated with already running threads to obtain the new memory device BW demand. Accordingly, the memory device BW that will be allocated is proactive, based on the thread workload characteristics in the past. Based on this new memory device BW demand, a DVFS point is chosen for the memory device.

As already noted, the illustrated PUNIT 40 includes two registers per HW thread (in each logical processor) holding the average BW and maximum BW demand of the thread in question. A hardware adder can be implemented to accumulate the average BW register of all the threads 60. A similar adder is used for the maximum (peak) BW register. This HW implementation enables faster calculation of the BW demand. A firmware (FW) implementation is also possible, but such an implementation may increase delay overhead depending on the implementation.

Another option (e.g., Option #2) biases the bandwidth demand for high priority threads by using the maximum BW consumption instead of the average BW consumption to determine the minimum bandwidth demand (e.g., so that there is no performance impact to high priority threads). In such a case, the below formulas may be used.

Min memory device BW demand=average BW for normal priority threads+maximum BW for high priority threads+memory device utilization by Uncore

Maximum (Peak) memory device BW demand=maximum BW of each thread+memory device utilization by Uncore

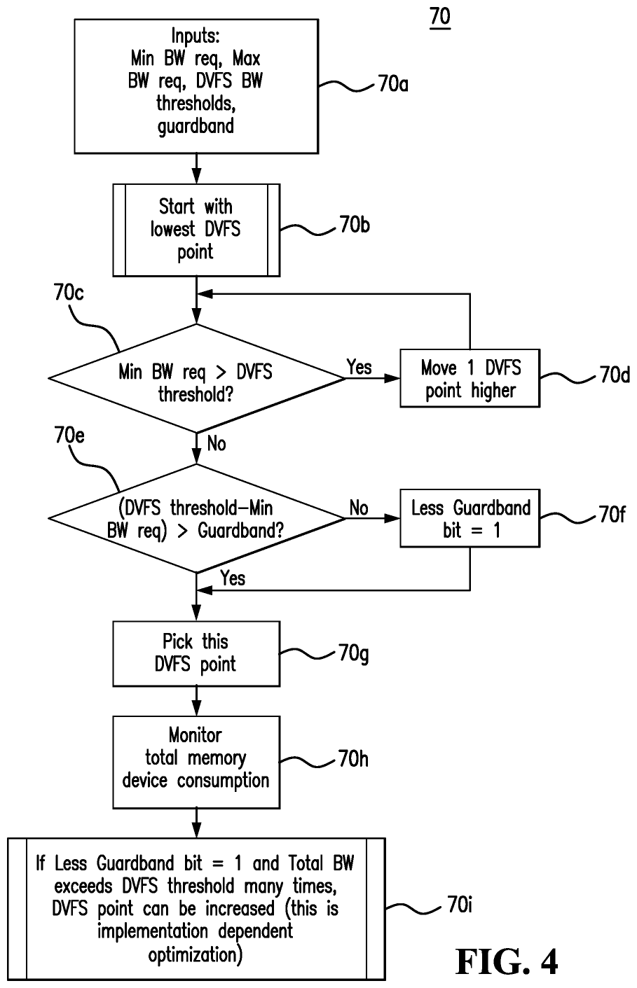

FIG. 4 shows a method 70 (70a-70i) of choosing a DVFS point. The method 70 may generally be implemented in logic hardware such as, for example, the DVFS point selection block 64 (FIG. 2), already discussed. More particularly, the method 70 may be implemented in one or more modules as a set of logic instructions stored in a machine- or computer-readable storage medium such as random access memory (RAM), read only memory (ROM), programmable ROM (PROM), firmware, flash memory, etc., in configurable hardware such as, for example, programmable logic arrays (PLAs), field programmable gate arrays (FPGAs), complex programmable logic devices (CPLDs), in fixed-functionality hardware using circuit technology such as, for example, application specific integrated circuit (ASIC), complementary metal oxide semiconductor (CMOS) or transistor-transistor logic (TTL) technology, or any combination thereof.

The illustrated processing block 70a receives a minimum bandwidth demand (e.g., requirement/“req”), a maximum demand, DVFS bandwidth thresholds, and a guardband as inputs. Block 70b starts with the lowest DVFS point, wherein a determination is made at block 70c as to whether the minimum bandwidth demand is greater than the DVFS threshold. If so, block 70d moves the DVFS setting one point higher and returns to block 70c. When it is determined at block 70c that the DVFS threshold is not exceeded by the minimum bandwidth demand, block 70e determines whether the difference between the DVFS threshold and the minimum bandwidth demand exceeds the guardband value. If not, block 70f sets a “less” guardband bit to one. Illustrated block 70g selects the current DVFS point, wherein block 70h monitors the total memory device bandwidth consumption. If the less guardband bit is one and the total memory device bandwidth consumption exceeds the DVFS threshold a relatively large number of times, block 70i increases the DVFS point.

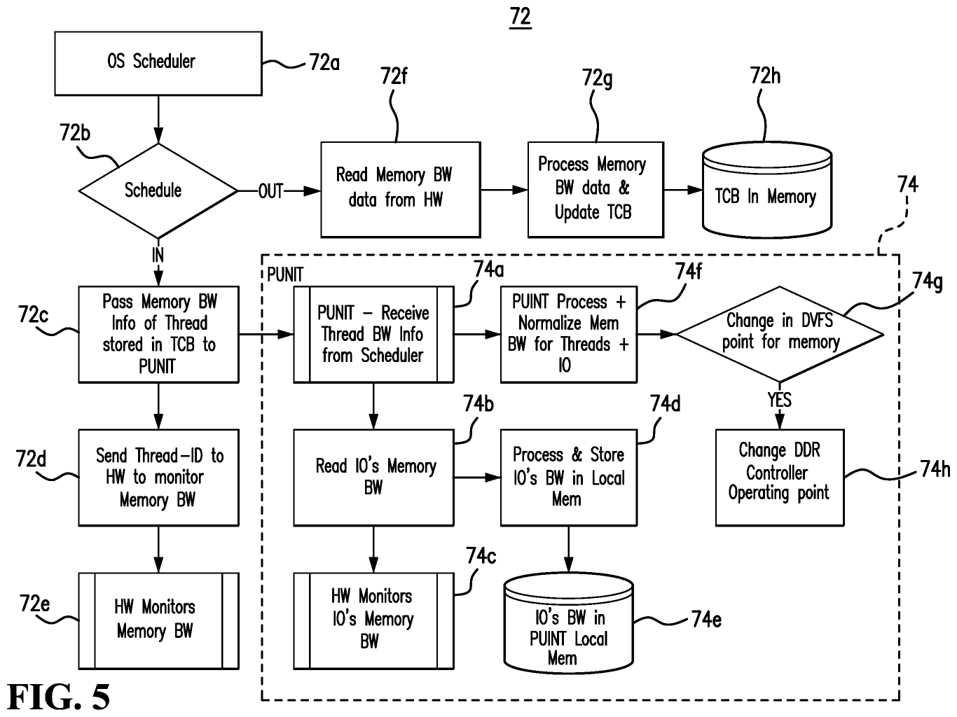

FIG. 5 shows a method 72 (72a-72h) of operating an OS scheduler and monitoring hardware and a method 74 (74a-74h) of operating a PUNIT in a memory bandwidth monitoring (MBM) architecture (e.g., a Resource Descriptor Technology/RDT feature from INTEL). The methods 72, 74 may be implemented in one or more modules as a set of logic instructions stored in a machine- or computer-readable storage medium such as RAM, ROM, PROM, firmware, flash memory, etc., in configurable hardware such as, for example, PLAs, FPGAs, CPLDs, in fixed-functionality hardware using circuit technology such as, for example, ASIC, CMOS or TTL technology, or any combination thereof.

Illustrated processing block 72a initiates an OS scheduler, which determines at block 72b whether an application thread is to be scheduled in or out. If the thread is to be scheduled out, scheduler block 72c passes memory bandwidth information of the thread stored in the TCB to the PUNIT method 74. Additionally, scheduler block 72d sends the thread ID to hardware, wherein hardware block 72e uses the thread ID to monitor memory bandwidth consumption. In one example, scheduler block 72d optimizes performance by bypassing the transmission of memory bandwidth information for threads of a relatively short duration (e.g., kernel threads, interrupt threads). PUNIT block 74a receives the thread bandwidth information from the scheduler and PUNIT block 74b reads the IO memory bandwidth consumption. In an embodiment, hardware monitors the 10 memory bandwidth consumption at PUNIT block 74c. Additionally, PUNIT block 74d processes and stores the IO bandwidth consumption in local memory 74e. PUNIT block 74f sums bandwidth consumption for the PUNIT process, the normalized bandwidth consumption for the threads and the bandwidth consumption for the IO, where PUNIT block 74g determines whether a change in the DVFS set point is appropriate. If so, PUNIT block 74h changes the DDR controller operating point.

If it is determined at scheduler block 72b that a thread is to be scheduled out, scheduler block 72f reads memory bandwidth data from hardware. Scheduler block 72g then processes the memory bandwidth data and updates the TCB in a memory 72h.

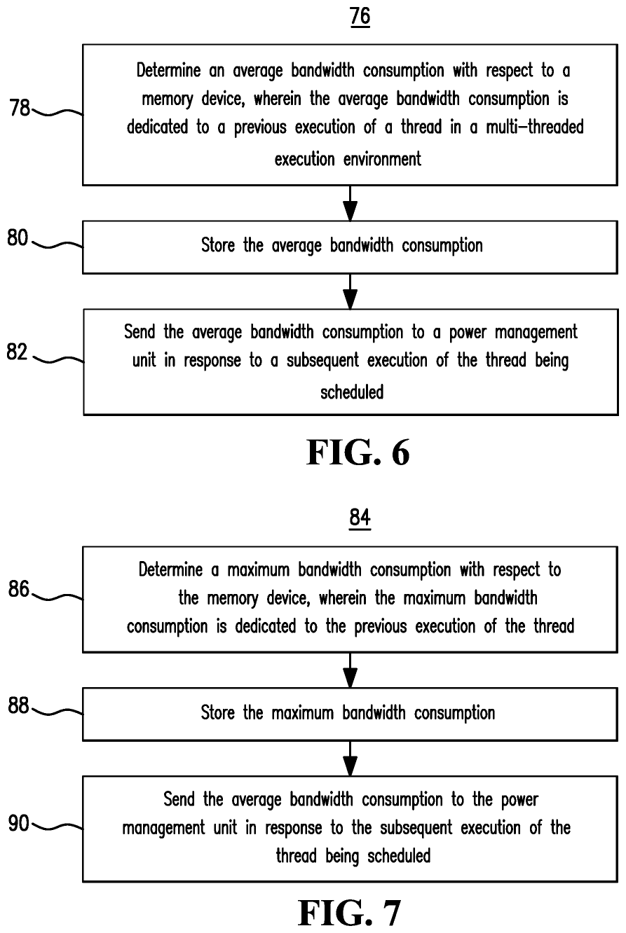

FIG. 6 shows a method 76 of operating an OS scheduler. The method 76 may generally be implemented in an OS scheduler such as, for example, the OS scheduler 36 (FIG. 2), already discussed. More particularly, the method 76 may be implemented in one or more modules as a set of logic instructions stored in a machine- or computer-readable storage medium such as RAM, ROM, PROM, firmware, flash memory, etc.

For example, computer program code to carry out operations shown in the method 76 may be written in any combination of one or more programming languages, including an object oriented programming language such as JAVA, SMALLTALK, C++ or the like and conventional procedural programming languages, such as the “C” programming language or similar programming languages. Additionally, logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

In general, a software application may exhibit behavioral changes with respect to user inputs, context, etc. Additionally, application developers may request peak memory performance to improve the performance of the application. As a result, the memory bandwidth demand may vary depending on phases of workload execution. The method 76 profiles this variability over time to understand usage requirements.

Illustrated processing block 78 provides for determining an average bandwidth consumption with respect to a memory device, wherein the average bandwidth consumption is dedicated to a previous execution of a thread in a multi-threaded execution environment. In an embodiment, block 78 includes receiving a total bandwidth consumption from a hardware monitor, wherein the average bandwidth consumption is determined based on the total bandwidth consumption and a duration of the previous execution of the thread. Block 80 stores the average bandwidth consumption. In one example, block 80 stores the average bandwidth consumption to a TCB data structure. Block 82 sends the average bandwidth consumption to a power management unit (e.g., PUNIT) in response to a subsequent execution of the thread being scheduled.

In an embodiment, block 82 sends the average bandwidth consumption to the power management controller only if the duration of one or more of the previous execution or the subsequent execution exceeds a time threshold (e.g., the thread is a kernel or interrupt thread). In such a case, block 82 may withhold the average bandwidth consumption from the power management controller if the duration of one or more of the previous execution or the subsequent execution does not exceed the time threshold.

Additionally, block 82 may send the average bandwidth consumption to the power management controller via a TPMI. In another example, block 82 may send the average bandwidth consumption to the power management controller via a FAST MSR. In such a case, block 82 confirms that a first portion of the average bandwidth consumption and a second portion of the average bandwidth consumption are visible outside a logical processor (e.g., associated with the thread) and writes the first portion while the second portion is in transit on the logical processor. The method 76 may be repeated for a plurality of simultaneous/concurrent threads in the multi-threaded execution environment. The illustrated method 76 therefore enhances performance at least to the extent that proactively dedicating the average bandwidth consumption to the thread eliminates or reduces the occurrence of frequency increases in the memory device that are either too long or unnecessary altogether. Moreover, sending the average bandwidth consumption via a TPMI or FAST MSR further enhances performance by reducing latency.

FIG. 7 shows another method 84 of operating an OS scheduler. The method 76 may generally be implemented in conjunction with the method 76 (FIG. 6) in an OS scheduler such as, for example, the OS scheduler 36 (FIG. 2), already discussed. More particularly, the method 84 may be implemented in one or more modules as a set of logic instructions stored in a machine- or computer-readable storage medium such as RAM, ROM, PROM, firmware, flash memory, etc.

Illustrated processing block 86 determines a maximum (e.g., peak) bandwidth consumption with respect to the memory device, wherein the maximum bandwidth consumption is dedicated to the previous execution of the thread (e.g., in the multi-threaded execution environment). Block 88 provides for storing the maximum bandwidth consumption. In one example, block 88 stores the maximum bandwidth consumption to a TCB data structure. Block 90 sends the maximum bandwidth consumption to a power management unit (e.g., PUNIT) in response to a subsequent execution of the thread being scheduled.

In an embodiment, block 90 sends the maximum bandwidth consumption to the power management controller only if the duration of one or more of the previous execution or the subsequent execution exceeds a time threshold (e.g., the thread is a kernel or interrupt thread). In such a case, block 90 may withhold the maximum bandwidth consumption from the power management controller if the duration of one or more of the previous execution or the subsequent execution does not exceed the time threshold.

Additionally, block 90 may send the maximum bandwidth consumption to the power management controller via a TPMI. In another example, block 90 may send the maximum bandwidth consumption to the power management controller via a FAST MSR. In such a case, block 90 confirms that a first portion of the maximum bandwidth consumption and a second portion of the maximum bandwidth consumption are visible outside a logical processor (e.g., associated with the thread) and writes the first portion while the second portion is in transit on the logical processor. The method 84 may be repeated for a plurality of simultaneous threads in the multi-threaded execution environment. The illustrated method 84 therefore enhances performance at least to the extent that proactively dedicating the maximum bandwidth consumption to the thread eliminates or reduces the occurrence of frequency increases in the memory device that are either too long or unnecessary altogether. Moreover, sending the maximum bandwidth consumption via a TPMI or FAST MSR further enhances performance by reducing latency.

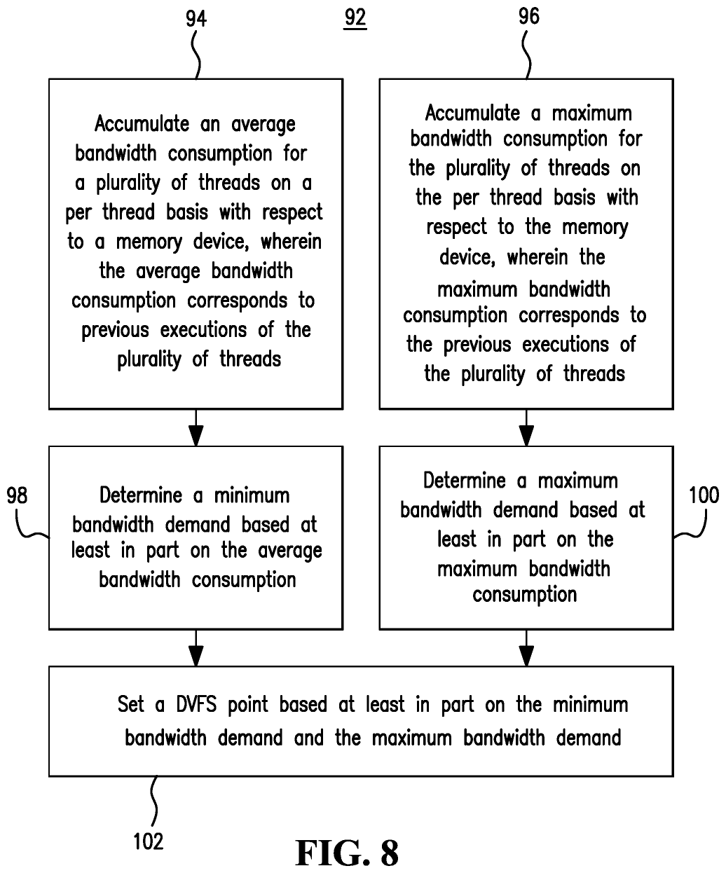

FIG. 8 shows a method 92 of operating logic hardware. The method 92 may generally be implemented in a power management unit such as, for example, the PUNIT 40 (FIG. 2), already discussed. More particularly, the method 92 may be implemented in configurable hardware such as, for example, PLAs, FPGAs, CPLDs, in fixed-functionality hardware using circuit technology such as, for example, ASIC, CMOS or TTL technology, or any combination thereof.

Illustrated processing block 94 provides for accumulating (e.g., via a first set of registers in the logic hardware) an average bandwidth consumption for a plurality of threads on a per thread basis with respect to a memory device, wherein the average bandwidth corresponds to previous executions of the plurality of threads. Additionally, block 96 may accumulate (e.g., via a second set of registers in the logic hardware) a maximum bandwidth consumption for the plurality of threads on the per thread basis. In the illustrated example, the maximum bandwidth consumption also corresponds to the previous executions of the plurality of threads. In an embodiment, block 96 uses a watermark register in the logic hardware to record the maximum bandwidth consumption.

Block 98 determines a minimum bandwidth demand based at least in part on the average bandwidth consumption. Block 100 determines a maximum bandwidth demand based at least in part on the maximum bandwidth consumption. In one example (e.g., Option #1), block 98 and/or block 100 also determine a non-thread (e.g., uncore) bandwidth consumption with respect to the memory device. In such a case, the minimum bandwidth demand may be determined further based on the non-thread bandwidth consumption (e.g., the sum of the average bandwidth consumption and the non-thread bandwidth consumption). Additionally, the maximum bandwidth demand may be determined further based on the non-thread bandwidth consumption (e.g., the sum of the maximum bandwidth consumption and the non-thread bandwidth consumption).

In another example (e.g., Option #2), the average bandwidth consumption corresponds to normal priority threads. In such a case, block 96 may accumulate the maximum bandwidth consumption for high priority threads on the per thread basis with respect to the memory device, wherein the maximum bandwidth consumption corresponds to previous executions of the high priority threads. Thus, block 98 may determine the minimum bandwidth consumption further based on the maximum bandwidth consumption (e.g., the sum of the average bandwidth consumption, the maximum bandwidth consumption for high priority threads, and the non-thread bandwidth consumption). Block 102 sets a DVFS point (e.g., operating frequency of the memory device) based at least in part on the minimum bandwidth demand. In the illustrated example, block 102 sets the DVFS point further based on the maximum bandwidth demand. In an embodiment, block 102 implements one or more aspects of the method 70 (FIG. 4), already discussed. The method 92 therefore enhances performance at least to the extent that proactively setting the DVFS point based on the minimum bandwidth demand eliminates or reduces frequency increases/spikes in the memory device that are either too long or unnecessary altogether.

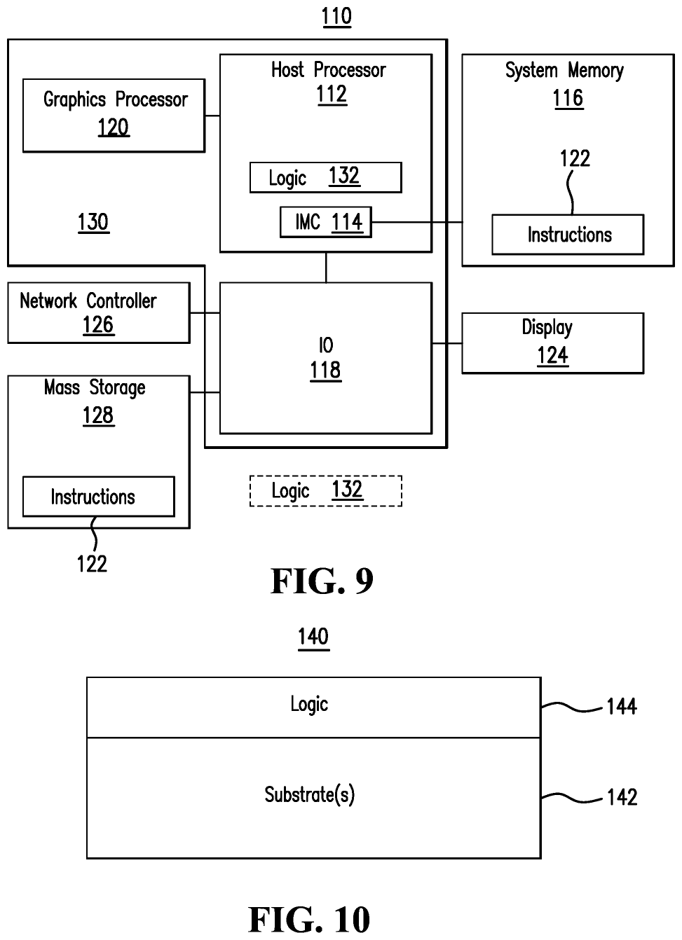

Turning now to FIG. 9, a performance-enhanced computing system 110 is shown. The system 110 may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IoT) functionality, etc., or any combination thereof

In the illustrated example, the system 110 includes a host processor 112 (e.g., CPU) having an integrated memory controller (IMC) 114 that is coupled to a system memory 116. In an embodiment, an 10 module 118 is coupled to the host processor 112. The illustrated I0 module 118 communicates with, for example, a display 124 (e.g., touch screen, liquid crystal display/LCD, light emitting diode/LED display), a network controller 126 (e.g., wired and/or wireless), and a mass storage 128 (e.g., hard disk drive/HDD, optical disc, solid-state drive/SSD, flash memory, etc.). The system 110 may also include a graphics processor 120 (e.g., graphics processing unit/GPU) that is incorporated with the host processor 112 and the 10 module 118 into a system on chip (SoC) 130.

In one example, the system memory 116 and/or the mass storage 128 includes a set of executable program instructions 122, which when executed by the SoC 130, cause the SoC 130 and/or the computing system 110 to implement one or more aspects of the method 76 (FIG. 6) and/or the method 84 (FIG. 7), already discussed. Thus, the SoC 130 may execute the instructions 122 to determine an average bandwidth consumption with respect to a memory device such as, for example, the system memory 116, wherein the average bandwidth consumption is dedicated to a previous execution of a thread in a multi-threaded execution environment. The SoC 130 may also execute the instructions 122 to store the average bandwidth consumption (e.g., to a TCB) and send the average bandwidth consumption to a power management unit in response to a subsequent execution of the thread being scheduled. In one example, the power management unit resides in logic hardware 132 (e.g., configurable and/or fixed-functionality hardware) of the host processor 112.

Additionally, the logic hardware 132 may include a first set of registers to accumulate an average bandwidth consumption for a plurality of threads on a per thread basis with respect to the system memory 116. In such a case, the average bandwidth consumption corresponds to previous executions of the plurality of threads and the logic hardware 132 implements one or more aspects of the method 92 (FIG. 8). Thus, the logic hardware 132 may determine a minimum bandwidth demand based at least in part on the average bandwidth consumption and set a DVFS point of the system memory 116 based at least in part on the minimum bandwidth demand.

The logic hardware 132 may also include a second set of registers to accumulate a maximum bandwidth consumption for the plurality of threads on the per thread basis with respect to the system memory 116, wherein the maximum bandwidth consumption corresponds to the previous executions of the plurality of threads. In such a case, the logic hardware 132 also determines the maximum bandwidth demand based at least in part on the maximum bandwidth consumption, wherein the DVFS point is set further based on the maximum bandwidth demand. The computing system 110 is therefore considered performance-enhanced at least to the extent that setting the DVFS point based on the minimum bandwidth demand eliminates or reduces frequency increases/spikes in the memory device that are either too long or unnecessary altogether. Although the logic hardware 132 is shown within the host processor 112, the logic hardware 132 may reside elsewhere in the computing system 110.

FIG. 10 shows a semiconductor apparatus 140 (e.g., chip and/or package). The illustrated apparatus 140 includes one or more substrates 142 (e.g., silicon, sapphire, gallium arsenide) and logic 144 (e.g., transistor array and other integrated circuit/IC components) coupled to the substrate(s) 142. In an embodiment, the logic 144 implements one or more aspects of the method 92 (FIG. 8), already discussed. Thus, the logic 144 may include a first set of registers to accumulate an average bandwidth consumption for a plurality of threads on a per thread basis with respect to a memory device, wherein the average bandwidth consumption corresponds to previous executions of the plurality of threads. The logic 144 may also determine a minimum bandwidth demand based at least in part on the average bandwidth consumption and set a DVFS point based at least in part on the minimum bandwidth demand. The semiconductor apparatus 140 is therefore performance-enhanced at least to the extent that setting the DVFS point based on the minimum bandwidth demand eliminates or reduces frequency increases/spikes in the memory device that are either too long or unnecessary altogether.

The logic 144 may be implemented at least partly in configurable or fixed-functionality hardware. In one example, the logic 144 includes transistor channel regions that are positioned (e.g., embedded) within the substrate(s) 142. Thus, the interface between the logic 144 and the substrate(s) 142 may not be an abrupt junction. The logic 144 may also be considered to include an epitaxial layer that is grown on an initial wafer of the substrate(s) 142.

### ADDITIONAL NOTES AND EXAMPLES

Example 1 includes a performance-enhanced computing system comprising a power management unit, a processing unit coupled to the power management units, and a memory device coupled to the processing unit, the memory device including a set of instructions, which when executed by the processing unit, cause the processing unit to determine an average bandwidth consumption with respect to the memory device, wherein the average bandwidth consumption is dedicated to a previous execution of a thread in a multi-threaded execution environment, store the average bandwidth consumption, and send the average bandwidth consumption to the power management in response to a subsequent execution of the thread being scheduled.

Example 2 includes the computing system of Example 1, wherein the instructions, when executed, further cause the power management unit to determine a maximum bandwidth consumption with respect to the memory device, wherein the maximum bandwidth consumption is dedicated to the previous execution of the thread, store the maximum bandwidth consumption, and send the maximum bandwidth consumption to the power management unit in response to the subsequent execution of the thread being scheduled.

Example 3 includes the computing system of Example 2, wherein the average bandwidth consumption and the maximum bandwidth consumption are stored to a thread control block data structure.

Example 4 includes the computing system of Example 1, wherein the instructions, when executed, further cause the computing system to receive a total bandwidth consumption from a hardware monitor, and wherein the average bandwidth consumption is determined based on the total bandwidth consumption and a duration of the previous execution of the thread.

Example 5 includes the computing system of any one of Examples 1 to 4, wherein the average bandwidth consumption is sent to the power management controller if a duration of one or more of the previous execution or the subsequent execution exceeds a threshold.

Example 6 includes the computing system of Example 5, wherein the instructions, when executed, further cause the computing system to withhold the average bandwidth consumption from the power management controller if the duration of one or more of the previous execution or the subsequent execution does not exceed the threshold.

Example 7 includes at least one computer readable storage medium comprising a set of instructions, which when executed by a computing system, cause the computing system to determine an average bandwidth consumption with respect to a memory device, wherein the average bandwidth consumption is dedicated to a previous execution of a thread in a multi-threaded execution environment, store the average bandwidth consumption, and send the average bandwidth consumption to a power management unit in response to a subsequent execution of the thread being scheduled.

Example 8 includes the at least one computer readable storage medium of Example 7, wherein the instructions, when executed, further cause the computing system to determine a maximum bandwidth consumption with respect to the memory device, wherein the maximum bandwidth consumption is dedicated to the previous execution of the thread, store the maximum bandwidth consumption, and send the maximum bandwidth consumption to the power management unit in response to the subsequent execution of the thread being scheduled.

Example 9 includes the at least one computer readable storage medium of Example 8, wherein the average bandwidth consumption and the maximum bandwidth consumption are stored to a thread control block data structure.

Example 10 includes the at least one computer readable storage medium of Example 7, wherein the instructions, when executed, further cause the computing system to receive a total bandwidth consumption from a hardware monitor, and wherein the average bandwidth consumption is determined based on the total bandwidth consumption and a duration of the previous execution of the thread.

Example 11 includes the at least one computer readable storage medium of any one of Examples 7 to 10, wherein the average bandwidth consumption is sent to the power management controller if a duration of one or more of the previous execution or the subsequent execution exceeds a threshold, and wherein the instructions, when executed, further cause the computing system to withhold the average bandwidth consumption from the power management controller if the duration of one or more of the previous execution or the subsequent execution does not exceed the threshold.

Example 12 includes the at least one computer readable storage medium of any one of Examples 7 to 10, wherein the average bandwidth consumption is sent to the power management controller via a topology aware register and power management capsule interface.

Example 13 includes the at least one computer readable storage medium of any one of Examples 7 to 10, wherein to send to the average bandwidth consumption to the power management controller, the instructions, when executed, cause the computing system to confirm that a first portion of the average bandwidth consumption and a second portion of the average bandwidth consumption are visible outside a logical processor, and write the first portion while the second portion is in transit on the logical processor.

Example 14 includes a semiconductor apparatus comprising one or more substrates, and logic coupled to the one or more substrates, wherein the logic is implemented at least partly in one or more of configurable or fixed-functionality hardware, wherein the logic includes a first set of registers to accumulate an average bandwidth consumption for a plurality of threads on a per thread basis with respect to a memory device, and wherein the average bandwidth consumption corresponds to previous executions of the plurality of threads, the logic to determine a minimum bandwidth demand based at least in part on the average bandwidth consumption, and set a dynamic voltage and frequency scaling (DVFS) point based at least in part on the minimum bandwidth demand.

Example 15 includes the semiconductor apparatus of Example 14, wherein the logic further includes a second set of registers to accumulate a maximum bandwidth consumption for the plurality of threads on the per thread basis with respect to the memory device, and wherein the maximum bandwidth consumption corresponds to the previous executions of the plurality of threads, the logic to determine a maximum bandwidth demand based at least in part on the maximum bandwidth consumption, wherein the DVFS point is set further based on the maximum bandwidth demand.

Example 16 includes the semiconductor apparatus of Example 15, wherein the logic is to determine a non-thread bandwidth consumption with respect to the memory device, and wherein the maximum bandwidth demand and the minimum bandwidth demand are determined further based on the non-thread bandwidth consumption.

Example 17 includes the semiconductor apparatus of Example 14, wherein the average bandwidth consumption corresponds to normal priority threads, wherein the logic further includes a second set of registers to accumulate a maximum bandwidth consumption for high priority threads on the per thread basis with respect to the memory device, wherein the maximum bandwidth consumption corresponds to previous executions of the high priority threads, and wherein the minimum bandwidth demand is determined further based on the maximum bandwidth consumption.

Example 18 includes the semiconductor apparatus of Example 17, wherein the logic is to determine a non-thread bandwidth consumption with respect to the memory device, and wherein the minimum bandwidth demand is determined further based on the non-thread bandwidth consumption.

Example 19 includes the semiconductor apparatus of any one of Examples 17 to 18, wherein the logic further includes a watermark register to record the maximum bandwidth consumption.

Example 20 includes a method of managing memory bandwidth allocation, the method comprising accumulating, by a first set of registers, an average bandwidth consumption for a plurality of threads on a per thread basis with respect to a memory device, wherein the average bandwidth consumption corresponds to previous executions of the plurality of threads, determining, by logic coupled to one or more substrates, a minimum bandwidth demand based at least in part on the average bandwidth consumption, and setting, by the logic coupled to one or more substrates, a dynamic voltage and frequency scaling (DVFS) point based at least in part on the minimum bandwidth demand.

Example 21 includes the method of Example 20, further including accumulating, by a second set of registers, a maximum bandwidth consumption for the plurality of threads on the per thread basis with respect to the memory device, wherein the maximum bandwidth consumption corresponds to the previous executions of the plurality of threads, and determining, by the logic coupled to one or more substrates, a maximum bandwidth demand based at least in part on the maximum bandwidth consumption, wherein the DVFS point is set further based on the maximum bandwidth demand.

Example 22 includes the method of Example 21, further including determining, by the logic coupled to the one or more substrates, a non-thread bandwidth consumption with respect to the memory device, wherein the maximum bandwidth demand and the minimum bandwidth demand are determined further based on the non-thread bandwidth consumption.

Example 23 includes the method of Example 20, wherein the average bandwidth consumption corresponds to normal priority threads, the method further including accumulating, by a second set of registers, a maximum bandwidth consumption for high priority threads on the per thread basis with respect to the memory device, wherein the maximum bandwidth consumption corresponds to previous executions of the high priority threads, and wherein the minimum bandwidth demand is determined further based on the maximum bandwidth consumption.

Example 24 includes the method of Example 23, further including determining a non-thread bandwidth consumption with respect to the memory device, wherein the minimum bandwidth demand is determined further based on the non-thread bandwidth consumption.

Example 25 includes the method of any one of Examples 23 to 24, further including recording, by a watermark register, the maximum bandwidth consumption.

Example 26 includes an apparatus comprising means for performing the method of any one of Examples 20 to 25.

Thus, technology described herein provides a proactive solution to choose DDR frequency (e.g., DVFS point) based on per-thread information available from the OS (e.g., through an MBM/RDT feature or something similar). Whenever a thread is scheduled, the DDR BW requirement is determined by technology in a PUNIT/Pcode and the optimal DDR frequency is then calculated to provide the required BW. The technology described herein uses the historic behavior of an application (e.g., captured by HW monitors and sent to OS for storage/processing) and applies the historic behavior to calculate DDR BW and frequency when the application is subsequently being scheduled in. Proactively setting the DDR frequency based on historic thread characteristics can help to avoid hysteresis applied in existing designs, which are reactive mechanisms.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a power management unit;
a processing unit coupled to the power management unit; and
a memory device coupled to the processing unit, the memory device including a set of instructions, which when executed by the processing unit, cause the processing unit to:
determine an average bandwidth consumption with respect to the memory device, wherein the average bandwidth consumption is dedicated to a previous execution of a thread in a multi-threaded execution environment,
store the average bandwidth consumption, and
send the average bandwidth consumption to the power management unit in response to a subsequent execution of the thread being scheduled.

2. The computing system of claim 1, wherein the instructions, when executed, further cause the power management unit to:
determine a maximum bandwidth consumption with respect to the memory device, wherein the maximum bandwidth consumption is dedicated to the previous execution of the thread,
store the maximum bandwidth consumption, and
send the maximum bandwidth consumption to the power management unit in response to the subsequent execution of the thread being scheduled.

3. The computing system of claim 2, wherein the average bandwidth consumption and the maximum bandwidth consumption are stored to a thread control block data structure.

4. The computing system of claim 1, wherein the instructions, when executed, further cause the computing system to receive a total bandwidth consumption from a hardware monitor, and wherein the average bandwidth consumption is determined based on the total bandwidth consumption and a duration of the previous execution of the thread.

5. The computing system of claim 1, wherein the average bandwidth consumption is sent to the power management controller if a duration of one or more of the previous execution or the subsequent execution exceeds a threshold.

6. The computing system of claim 5, wherein the instructions, when executed, further cause the computing system to withhold the average bandwidth consumption from the power management controller if the duration of one or more of the previous execution or the subsequent execution does not exceed the threshold.

7. At least one computer readable storage medium comprising a set of instructions, which when executed by a computing system, cause the computing system to:
determine an average bandwidth consumption with respect to a memory device, wherein the average bandwidth consumption is dedicated to a previous execution of a thread in a multi-threaded execution environment;
store the average bandwidth consumption; and
send the average bandwidth consumption to a power management unit in response to a subsequent execution of the thread being scheduled.

8. The at least one computer readable storage medium of claim 7, wherein the instructions, when executed, further cause the computing system to:
determine a maximum bandwidth consumption with respect to the memory device, wherein the maximum bandwidth consumption is dedicated to the previous execution of the thread;
store the maximum bandwidth consumption; and
send the maximum bandwidth consumption to the power management unit in response to the subsequent execution of the thread being scheduled.

9. The at least one computer readable storage medium of claim 8, wherein the average bandwidth consumption and the maximum bandwidth consumption are stored to a thread control block data structure.

10. The at least one computer readable storage medium of claim 7, wherein the instructions, when executed, further cause the computing system to receive a total bandwidth consumption from a hardware monitor, and wherein the average bandwidth consumption is determined based on the total bandwidth consumption and a duration of the previous execution of the thread.

11. The at least one computer readable storage medium of claim 7, wherein the average bandwidth consumption is sent to the power management controller if a duration of one or more of the previous execution or the subsequent execution exceeds a threshold, and wherein the instructions, when executed, further cause the computing system to withhold the average bandwidth consumption from the power management controller if the duration of one or more of the previous execution or the subsequent execution does not exceed the threshold.

12. The at least one computer readable storage medium of claim 7, wherein the average bandwidth consumption is sent to the power management controller via a topology aware register and power management capsule interface.

13. The at least one computer readable storage medium of claim 7, wherein to send to the average bandwidth consumption to the power management controller, the instructions, when executed, cause the computing system to:
confirm that a first portion of the average bandwidth consumption and a second portion of the average bandwidth consumption are visible outside a logical processor; and
write the first portion while the second portion is in transit on the logical processor.

14. A semiconductor apparatus comprising:
one or more substrates; and
logic coupled to the one or more substrates, wherein the logic is implemented at least partly in one or more of configurable or fixed-functionality hardware, wherein the logic includes a first set of registers to accumulate an average bandwidth consumption for a plurality of threads on a per thread basis with respect to a memory device, and wherein the average bandwidth consumption corresponds to previous executions of the plurality of threads, the logic to:
determine a minimum bandwidth demand based at least in part on the average bandwidth consumption; and
set a dynamic voltage and frequency scaling (DVFS) point based at least in part on the minimum bandwidth demand.

15. The semiconductor apparatus of claim 14, wherein the logic further includes a second set of registers to accumulate a maximum bandwidth consumption for the plurality of threads on the per thread basis with respect to the memory device, and wherein the maximum bandwidth consumption corresponds to the previous executions of the plurality of threads, the logic to:
determine a maximum bandwidth demand based at least in part on the maximum bandwidth consumption, wherein the DVFS point is set further based on the maximum bandwidth demand.

16. The semiconductor apparatus of claim 15, wherein the logic is to determine a non-thread bandwidth consumption with respect to the memory device, and wherein the maximum bandwidth demand and the minimum bandwidth demand are determined further based on the non-thread bandwidth consumption.

17. The semiconductor apparatus of claim 14, wherein the average bandwidth consumption corresponds to normal priority threads, wherein the logic further includes a second set of registers to accumulate a maximum bandwidth consumption for high priority threads on the per thread basis with respect to the memory device, wherein the maximum bandwidth consumption corresponds to previous executions of the high priority threads, and wherein the minimum bandwidth demand is determined further based on the maximum bandwidth consumption.

18. The semiconductor apparatus of claim 17, wherein the logic is to determine a non-thread bandwidth consumption with respect to the memory device, and wherein the minimum bandwidth demand is determined further based on the non-thread bandwidth consumption.

19. The semiconductor apparatus of claim 17, wherein the logic further includes a watermark register to record the maximum bandwidth consumption.

20. A method comprising:
accumulating, by a first set of registers, an average bandwidth consumption for a plurality of threads on a per thread basis with respect to a memory device, wherein the average bandwidth consumption corresponds to previous executions of the plurality of threads;
determining, by logic coupled to one or more substrates, a minimum bandwidth demand based at least in part on the average bandwidth consumption; and
setting, by the logic coupled to one or more substrates, a dynamic voltage and frequency scaling (DVFS) point based at least in part on the minimum bandwidth demand.

21. The method of claim 20, further including:
accumulating, by a second set of registers, a maximum bandwidth consumption for the plurality of threads on the per thread basis with respect to the memory device, wherein the maximum bandwidth consumption corresponds to the previous executions of the plurality of threads; and
determining, by the logic coupled to one or more substrates, a maximum bandwidth demand based at least in part on the maximum bandwidth consumption, wherein the DVFS point is set further based on the maximum bandwidth demand.

22. The method of claim 21, further including determining, by the logic coupled to the one or more substrates, a non-thread bandwidth consumption with respect to the memory device, wherein the maximum bandwidth demand and the minimum bandwidth demand are determined further based on the non-thread bandwidth consumption.

23. The method of claim 20, wherein the average bandwidth consumption corresponds to normal priority threads, the method further including accumulating, by a second set of registers, a maximum bandwidth consumption for high priority threads on the per thread basis with respect to the memory device, wherein the maximum bandwidth consumption corresponds to previous executions of the high priority threads, and wherein the minimum bandwidth demand is determined further based on the maximum bandwidth consumption.

24. The method of claim 23, further including determining a non-thread bandwidth consumption with respect to the memory device, wherein the minimum bandwidth demand is determined further based on the non-thread bandwidth consumption.

25. The method of claim 23, further including recording, by a watermark register, the maximum bandwidth consumption.
